(19) United States
(12) Patent Application Publication
(10) Pub. No.: US 2026/0059648 A1
(43) Pub. Date: Feb. 26, 2026

(54) MULTILAYER SUBSTRATE AND ELECTRONIC DEVICE

(71) Applicant: Murata Manufacturing Co., Ltd., Nagaokakyo-shi (JP)

(72) Inventors: Nobuo IKEMOTO, Nagaokakyo-shi (JP); Masanori OKAMOTO, Nagaokakyo-shi (JP)

(21) Appl. No.: 19/375,775

(22) Filed: Oct. 31, 2025

Related U.S. Application Data
(63) Continuation of application No. PCT/JP2024/015875, filed on Apr. 23, 2024.

(30) Foreign Application Priority Data
May 17, 2023 (JP) 2023-081874

(51) Int. Cl. H05K 1/02

(52) U.S. Cl. CPC H05K 1/0218; H05K 1/0237

(57) ABSTRACT

A multilayer substrate includes conductor layer-formed resin layers each including a conductor layer on a resin layer, a first conductor layer-formed resin layer in which a first conductor layer is on one principal surface, and a second conductor layer-formed resin layer in which a second conductor layer is on one principal surface. At least a portion of the first conductor layer is a signal line. At least a portion of the second conductor layer is a ground electrode. A hollow portion in which a resin of the resin layer of a region of the first conductor layer-formed resin layer including a portion overlapped by the signal line is absent and to which the signal line is exposed, is provided. A thickness of the signal line in the hollow portion is smaller than a thickness of the first conductor layer at a portion other than in the hollow portion.

### CROSS REFERENCE TO RELATED APPLICATIONS

This application claims the benefit of priority to Japanese Patent Application No. 2023-081874 filed on May 17, 2023 and is a Continuation Application of PCT Application No. PCT/JP2024/015875 filed on Apr. 23, 2024. The entire contents of each application are hereby incorporated herein by reference.

### BACKGROUND OF THE INVENTION

### 1. Field of the Invention

The present invention relates to multilayer substrates each including a hollow portion and electronic devices including the multilayer substrates.

### 2. Description of the Related Art

A substrate for high-speed transmission using a flex substrate composed of copper foil and an insulating base material made of a resin is disclosed in Japanese Unexamined Patent Application Publication No. 2002-118361. This substrate for high-speed transmission, on a laminated substrate having signal wiring for high-speed transmission and obtained by stacking substrates in which the periphery of the signal wiring is composed of an air layer, uses, as a laminated unit substrate, a flex substrate of a structure having an adhesive agent made of a thermoplastic resin used both between the copper foil and the insulating base material made of a resin and on the lower surface of the insulating base material made of a resin.

### SUMMARY OF THE INVENTION

In the laminated substrate disclosed in Japanese Unexamined Patent Application Publication No. 2002-118361, an adhesive layer is required in order to ensure adhesive force of the copper foil. However, although the surface of the copper foil is generally roughened for the improvement in the adhesive force, in a high frequency, skin resistance is increased due to the influence of roughening, and transmission loss is increased.

Example embodiments of the present invention provide, in multilayer substrates of structures in which signal lines extend through hollow portions, that is, signal lines are partially in contact with hollow portions, multilayer substrates in which the high-frequency characteristics of the signal lines in the hollow portions in which the signal lines are not supported are improved, and electronic devices including such multilayer substrates.
(1) A multilayer substrate according to an example embodiment of the present disclosure is a multilayer substrate including a plurality of conductor layer-formed resin layers each including a conductor layer on a principal surface of a resin layer, and the conductor layer-formed resin layers include a first conductor layer-formed resin layer in which a first conductor layer is on one principal surface, and a second conductor layer-formed resin layer in which a second conductor layer is on one principal surface, at least a portion of the first conductor layer is a signal line, at least a portion of the second conductor layer is a ground electrode, a hollow portion in which a resin of the resin layer of a region of the first conductor layer-formed resin layer including a portion overlapped by the signal line when viewed in a direction of the stacking is absent and to which the signal line is exposed is provided, and a thickness of the signal line in the hollow portion is smaller than a thickness of the first conductor layer at a portion other than in the hollow portion.
(2) A multilayer substrate according to an example embodiment of the present disclosure is a multilayer substrate including a plurality of conductor layer-formed resin layers each including a conductor layer on a principal surface of a resin layer, and the conductor layer-formed resin layers include a first conductor layer-formed resin layer in which a first conductor layer is on one principal surface, and a second conductor layer-formed resin layer in which a second conductor layer is on one principal surface, at least a portion of the first conductor layer is a signal line, at least a portion of the second conductor layer is a ground electrode, a hollow portion in which a resin of the resin layer of a region of the second conductor layer-formed resin layer including a portion overlapped by the signal line when viewed in a direction of the stacking is absent and to which the ground electrode is exposed is provided, and a thickness of the ground electrode in the hollow portion is smaller than a thickness of the ground electrode other than in the hollow portion.
(3) An electronic device according to an example embodiment of the present disclosure includes the multilayer substrate and a processing portion to process a high-frequency signal propagating through the multilayer substrate.

In each of multilayer substrates according to example embodiments of the present invention, in a multilayer substrate of a structure in which a signal line is partially in contact with a hollow portion, a multilayer substrate in which the high-frequency characteristics of the signal line in the hollow portion in which the signal line is not supported are improved, and electronic devices including such multilayer substrate are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A to 1C are cross-sectional views of a conductor layer configuring a portion of a multilayer substrate according to a first example embodiment of the present invention.

FIGS. 2A to 2D are cross-sectional views of respective stages during manufacturing of the multilayer substrate according to the first example embodiment of the present invention.

FIGS. 3A and 3B are cross-sectional views of the multilayer substrate 101 according to the present first example embodiment of the present invention.

FIGS. 4A to 4D are cross-sectional views of respective stages during manufacturing of a multilayer substrate according to a second example embodiment of the present invention.

FIGS. 5A and 5B are cross-sectional views of the multilayer substrate 102 according to the second example embodiment of the present invention.

FIGS. 6A to 6D are cross-sectional views of respective stages during manufacturing of a multilayer substrate according to a third example embodiment of the present invention.

FIGS. 7A and 7B are cross-sectional views of the multilayer substrate 103 according to the third example embodiment of the present invention.

FIGS. 8A to 8D are cross-sectional views of respective stages during manufacturing of a multilayer substrate according to a fourth example embodiment of the present invention.

FIGS. 9A and 9B are cross-sectional views of the multilayer substrate 104 according to the fourth example embodiment of the present invention.

FIGS. 10A and 10B are cross-sectional views of a multilayer substrate 105 according to a fifth example embodiment of the present invention.

FIGS. 11A and 11B are cross-sectional views of a multilayer substrate 106 according to a sixth example embodiment of the present invention.

FIGS. 12A and 12B are cross-sectional views of a multilayer substrate 107 according to a seventh example embodiment of the present invention.

FIGS. 13A and 13B are cross-sectional views of a multilayer substrate 108 according to an eighth example embodiment of the present invention.

FIGS. 14A and 14B are cross-sectional views of a multilayer substrate 109 according to a ninth example embodiment of the present invention.

FIG. 15 is a block diagram showing a configuration of an electronic device 201 according to the ninth example embodiment of the present invention.

FIG. 16 is a view showing one example of a cross-sectional photograph that has captured a signal line 24.

FIG. 17 is a view showing another example of a cross-sectional photograph that has captured the signal line 24.

### DETAILED DESCRIPTION OF THE EXAMPLE EMBODIMENTS

A multilayer substrate according to a first example embodiment of the present invention is a multilayer substrate including a plurality of conductor layer-formed resin layers each obtained by forming a conductor layer on a principal surface of a resin layer, and is a multilayer substrate including a layer of the resin layer of a simple body that does not include the conductor layer as needed. The conductor layer-formed resin layers include a first conductor layer-formed resin layer in which a first conductor layer is on one principal surface, and a second conductor layer-formed resin layer in which a second conductor layer is on one principal surface. At least a portion of the first conductor layer is a signal line, and at least a portion of the second conductor layer is a ground electrode. A hollow portion in which a resin of the resin layer of a region of the first conductor layer-formed resin layer including a portion overlapped by the signal line when viewed in a direction of the stacking is absent and to which the signal line is exposed is provided. A thickness of the signal line in the hollow portion is formed to be smaller than a thickness of the first conductor layer at a portion other than in the hollow portion by etching or the like.

A multilayer substrate according to a second example embodiment of the present invention is a multilayer substrate including a plurality of conductor layer-formed resin layers each obtained by forming a conductor layer on a principal surface of a resin layer, and is a multilayer substrate including a layer of the resin layer of a simple body that does not include the conductor layer as needed. The conductor layer-formed resin layers include a first conductor layer-formed resin layer in which a first conductor layer is on one principal surface, and a second conductor layer-formed resin layer in which a second conductor layer is on one principal surface. At least a portion of the first conductor layer is a signal line, and at least a portion of the second conductor layer is a ground electrode. A hollow portion in which a resin of the resin layer of a region of the second conductor layer-formed resin layer including a portion overlapped by the signal line when viewed in a direction of the stacking is absent and to which the ground electrode is exposed is provided. A thickness of the ground electrode in the hollow portion is formed to be smaller than a thickness of the ground electrode other than in the hollow portion by etching or the like.

### First Example Embodiment

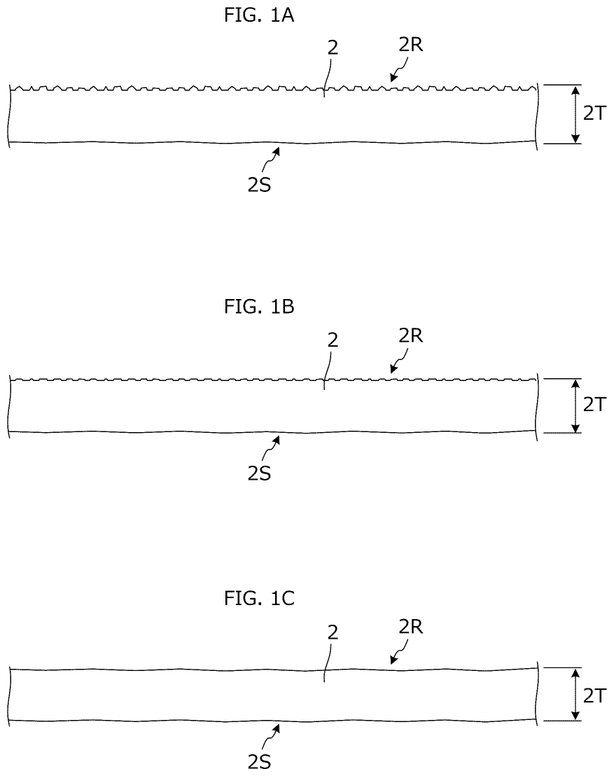

FIGS. 1A to 1C are cross-sectional views of a conductor layer configuring a portion of a multilayer substrate according to a first example embodiment. In FIGS. 1A to 1C, the conductor layer 2 includes copper foil, for example, and includes one principal surface 2R and a different principal surface 2S. However, hatching is omitted in these drawings.

The state shown in FIG. 1A is a cross-sectional view before machining (in an initial state) of the conductor layer 2, and the one principal surface 2R has a rough surface while the different principal surface 2S has a smooth surface.

The state shown in FIG. 1B is a cross-sectional view in a state in which the conductor layer 2 is smoothed to some extent, and the one principal surface 2R has a rough surface that is smoothed to some extent while the different principal surface 2S has a smooth surface.

The state shown in FIG. 1C is a cross-sectional view in a state in which the conductor layer 2 is further smoothed and each of the one principal surface 2R and the different principal surface 2S has a smoothed surface. The conductor layer 2 is, for example, copper foil.

As shown below, each of the one principal surface 2R and the different principal surface 2S in the above-described state is effectively used.

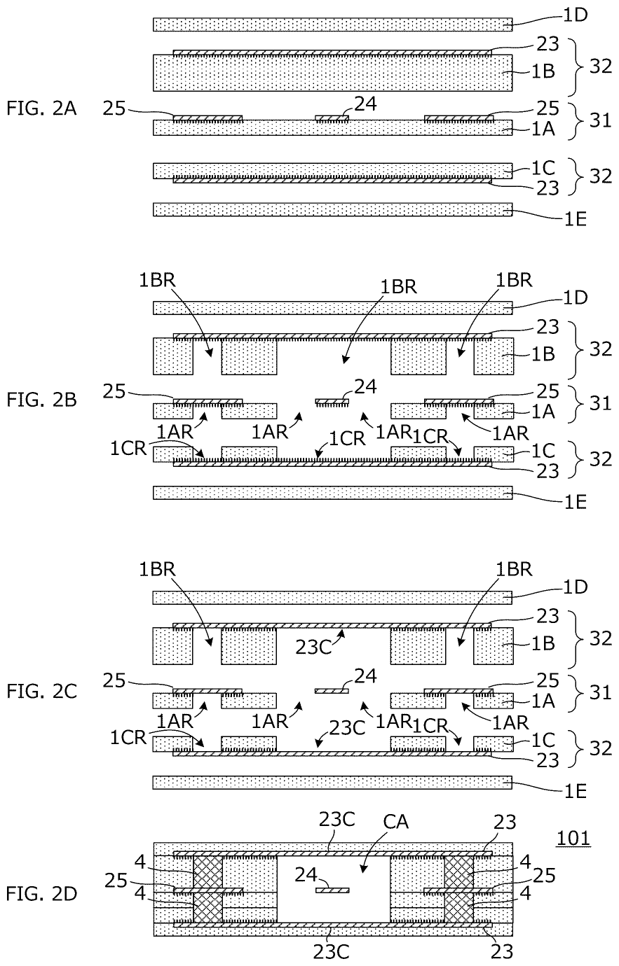

FIGS. 2A to 2D are cross-sectional views of respective stages during manufacturing of the multilayer substrate according to the present example embodiment. FIG. 2D is a cross-sectional view at the time of completion of the manufacturing. However, in FIGS. 2A to 2D, a rough surface as one principal surface of each resin layer is illustrated so as to be arranged with simple projection portions. In addition, the smooth surface as a different principal surface of each resin layer is illustrated in a simple straight line.

The multilayer substrate 101 of the present example embodiment shown in FIG. 2D includes resin layers 1D and 1E each of which has no conductor layer, and a single first conductor layer-formed resin layer 31 and two second conductor layer-formed resin layers 32 both of which have the conductor layer that are all shown in FIG. 2A.

A non-limiting example of a method of manufacturing the multilayer substrate 101 is as follows.

First, as shown in FIG. 2A, as each layer before stacking, the resin layer 1E, the lower second conductor layer-formed resin layer 32, the first conductor layer-formed resin layer 31, the upper second conductor layer-formed resin layer 32, and the resin layer 1D are provided. The first conductor layer-formed resin layer 31 is a layer on which a signal line 24 and a ground electrode (a lateral ground electrode) 25 are formed on a resin layer 1A. In addition, the upper second conductor layer-formed resin layer 32 is a layer on which a ground electrode 23 is formed on a resin layer 1B. Similarly, the lower second conductor layer-formed resin layer 32 is a layer on which the ground electrode 23 is formed on a resin layer 1C.

Next, as shown in FIG. 2B, a resin removal portion 1AR is formed at a plurality of places in the resin layer 1A. A resin removal portion 1BR is formed at a plurality of places in the resin layer 1B. Similarly, a resin removal portion 1CR is formed at a plurality of places in the resin layer 1C. Such resin removal is performed by forming a resist mask pattern at a place in which the resin removal is not performed, and, for example, immersing into an alkaline solution or irradiating with laser light.

Next, the signal line 24 and ground electrode 25 of the single first conductor layer-formed resin layer 31 shown in FIG. 2B are etched. In addition, the ground electrode 23 of each of the two second conductor layer-formed resin layers 32 shown in FIG. 2B is etched. For example, copper foil surface treatment is performed with a soft etching acid solution. At this time, the removal of a roughened portion of the copper foil and the removal of a rust-prevention layer are also possible. According to this, as shown in FIG. 2C, the surface of the signal line 24 is smoothed (roughening is reduced). In this etching step, since the one principal surface of the ground electrode 25 is embedded in the resin layer 1A, the bonding strength between the one principal surface of the ground electrode 25 and the resin layer 1A is not reduced.

Next, the ground electrode 23 of each of the two second conductor layer-formed resin layers 32 shown in FIG. 2B is etched. According to this, as shown in FIG. 2C, the ground electrode 23C in the hollow portion of the ground electrode 23 of a portion opened by the resin removal portion 1BR of the resin layer 1B is smoothed (roughening is reduced).

It is to be noted that a ground electrode surface may be coated in order to prevent oxidization of the ground electrodes 23 and 25. Similarly, the surface of the signal line 24 may be coated in order to reduce oxidization of the signal line 24. For example, gold plating treatment, water-soluble preflux treatment, or the like may be applied. In addition, a copper-oxide coating film may be made on the surface by oxidizing the surface of the signal line 24 and the ground electrodes 23 and 25.

It is to be noted that an anti-corrosion layer may be provided by applying anti-corrosion treatment to a surface of the signal line 24 exposed to a place to be a hollow portion CA later. Similarly, an anti-corrosion layer may be provided by applying the anti-corrosion treatment to a surface of the ground electrodes 23 exposed to a place to be a hollow portion CA later. Such anti-corrosion treatment includes gold plating treatment, water-soluble preflux treatment, and oxidation treatment, for example. The anti-corrosion layer is a layer capable of significantly reducing progress of surface oxidization, such as the copper-oxide coating film formed by the oxidation treatment, or a gold coating film formed by the gold coating treatment. The anti-corrosion layer is able to significantly reduce a change with time of the characteristics accompanying with the progress of the surface oxidization.

Next, the multilayer substrate 101 is formed by embedding the interlayer connection conductor 4 in the resin removal portions 1AR, 1BR, and 1CR that are shown in FIG. 2C, and by stacking and heating all the layers as shown in FIG. 2D. For example, the interlayer connection conductor 4 is conductive paste or solder paste before heating. It is to be noted that the interlayer connection conductor 4 may be formed by opening a through hole in a state in which respective layers are stacked and applying copper plating in this through hole.

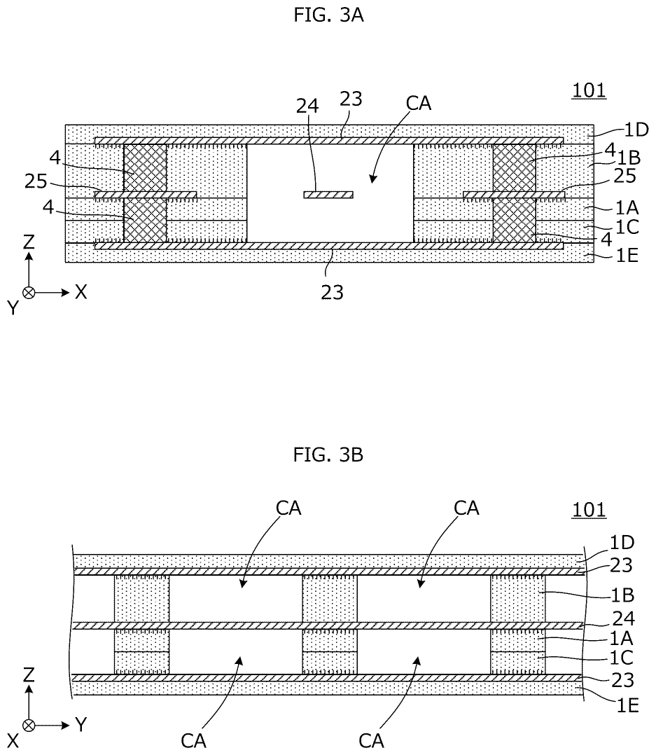

FIGS. 3A and 3B are cross-sectional views of the multilayer substrate 101 according to the present example embodiment. FIG. 3A is a cross-sectional view in the same completed state as the multilayer substrate 101 shown in FIG. 2D. It is a cross-sectional view of an X-Z plane. FIG. 3B is a cross-sectional view of a Y-Z plane.

As shown FIGS. 3A and 3B, the signal line 24 extends in a Y direction. Similarly, the ground electrodes 23 and 25 also extend in the Y direction. In this example, although the ground electrode 25 extends in the Y direction in the same manner as the ground electrode 23, the ground electrode 25 is also able to be applied to a case of forming only in an interlayer connection conductor portion.

The interlayer connection conductor 4 that appears in FIG. 3A electrically connects the upper and lower ground electrodes 23 through the ground electrode 25. In this manner, a coaxial line is configured by surrounding the periphery of the signal line 24 by the ground electrodes 23 and 25. The interlayer connection conductor 4 is arranged at predetermined intervals in the extension direction of the signal line 24. This interval is small to such an extent that the electromagnetic waves of the frequency band of the high-frequency signal propagating through the above-described coaxial line hardly leak to a lateral side (the X direction).

According to the present example embodiment, the following functional and advantageous effects are obtained.
(1) The roughening of the ground electrodes 23 and 25 (the copper foil) each of which is pressurized and adhered to the resin layers 1A, 1B, and 1C is large, so that the adhesive force between a resin portion and the copper foil is high.
(2) The roughening of a region of the ground electrodes 23 exposed in the hollow portion CA and a region of the signal line (the copper foil) 24 exposed in the hollow portion CA is small, so that the skin resistance of the signal line 24 is low and the transmission loss of high frequency is small. In particular, in comparison with the ground electrode 23, the roughening of the signal line 24 has a large effect on the transmission loss.
(3) The removal of the roughened portion of the copper foil is able to be easily performed by etching.
(4) In a case in which a nickel layer as a rust-prevention layer (an anti-corrosion layer) is formed on the surface of the copper foil, although the transmission loss causes a problem due to a high electric resistance value of the nickel layer, the nickel layer is removable by the above-described etching step, so that, in that sense, the transmission loss is able to be reduced.
(5) Although the portion of the ground electrode 23 in the hollow portion CA is in contact with air in the hollow portion CA, the roughening of the ground electrode 23 (the copper foil) is small. Therefore, an area in contact with air in this hollow portion CA is small, and the oxidization rate of the ground electrode 23 becomes slow.
(6) The interval between the signal line 24 and the ground electrode 23 is increased by etching the signal line 24 and reducing the thickness. Paradoxically, even when the interval between the signal line 24 and the ground electrode 23 is reduced, high high-frequency characteristics are maintainable by smoothing of the signal line 24 and the ground electrode 23, so that a thin multilayer substrate is able to be configured by reducing the interval between the signal line 24 and the ground electrode 23. It is to be noted that, even when the signal line 24 is thinned by etching, a resistance value of the signal line 24 is able to be reduced by increasing a line width of the signal line 24. This is able to reduce the transmission loss. In addition, the transmission line of predetermined characteristic impedance is easily obtained by setting of the line width of the signal line 24.
(7) A change in electrical characteristics over the years is able to be significantly reduced by coating the surface of the ground electrodes 23 and 25 and/or the surface of the signal line 24, or by forming an oxide film.

### Second Example Embodiment

A second example embodiment shows a multilayer substrate in which roughening of a region of the ground electrode 23 exposed in the hollow portion CA is further reduced.

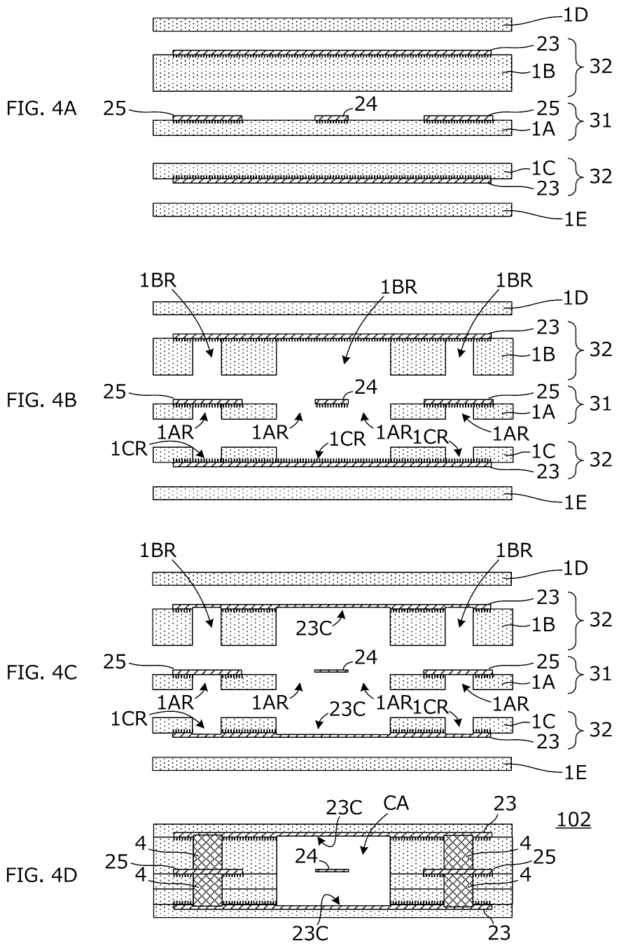

FIGS. 4A to 4D are cross-sectional views of respective stages during manufacturing of the multilayer substrate according to the present example embodiment. FIG. 4D is a cross-sectional view of the multilayer substrate 102 according to the present example embodiment.

The method of manufacturing the multilayer substrate 102 is almost the same as the method of manufacturing the multilayer substrate 101 shown in the first example embodiment. The state in FIG. 4A, FIG. 4B is the same as the state shown in FIG. 2A, FIG. 2B. In the step shown in FIG. 4C, the ground electrode 23 of the two second conductor layer-formed resin layers 32 shown in FIG. 4B is etched more strongly than in the first example embodiment. According to this, as shown in FIG. 4C, the ground electrode 23C in the hollow portion of the ground electrode 23 of a portion opened by the resin removal portion 1BR of the resin layer 1B is further thinned (roughening is reduced). In addition, the signal line 24 is thinned by this strong etching.

Other configurations are the same as the configurations of the multilayer substrate 101 shown in the first example embodiment.

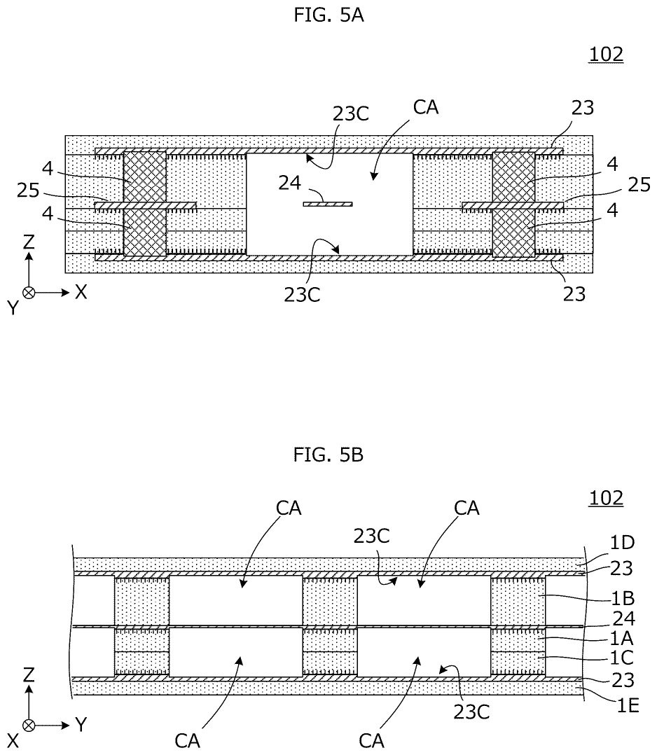

FIGS. 5A and 5B are cross-sectional views of the multilayer substrate 102 according to the present example embodiment. FIG. 5A is a cross-sectional view in the same completed state as the multilayer substrate 102 shown in FIG. 4D. It is a cross-sectional view of an X-Z plane. FIG. 5B is a cross-sectional view of a Y-Z plane. Although the structure of the multilayer substrate 101 of the present example embodiment is the same as the structure of the multilayer substrate 101 shown in FIGS. 3A and 3B in the first example embodiment, the ground electrode 23C exposed to the hollow portion CA is etched more strongly, so that the surface of the ground electrode 23C is further smoothed (roughening is reduced) in comparison with the first example embodiment. In addition, the signal line 24 is thinned by this strong etching.

According to the second example embodiment, the roughening of a region of the ground electrode 23 exposed in the hollow portion CA and the signal line (the copper foil) 24 is extremely small, so that the skin resistance of the signal line 24 is low and the transmission loss of high frequency is small. In addition, since the thickness in the hollow portion is able to be increased, much thinner multilayer substrate is configured.

### Third Example Embodiment

A third example embodiment exemplifies a multilayer substrate of which the roughened surface of the ground electrode is different from the example shown in the first and second example embodiments.

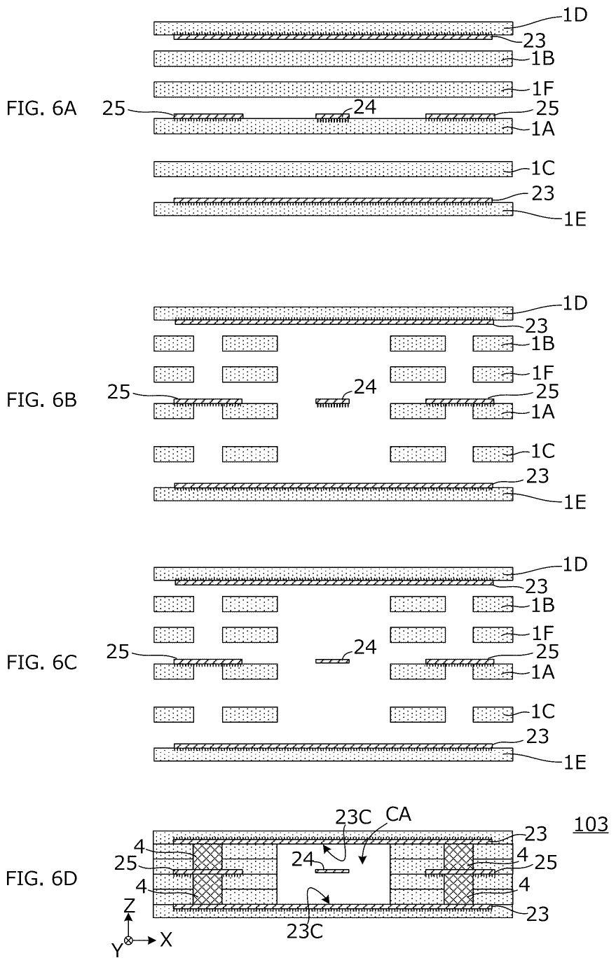

FIGS. 6A to 6D are cross-sectional views of respective stages during manufacturing of the multilayer substrate according to the present example embodiment. As shown in FIGS. 6B and 6C, a place in which the interlayer connection conductor 4 is to be formed is opened in the resin layers 1A, 1B, and 1C on which the ground electrodes 23 and 25 are formed. FIG. 6D is a cross-sectional view of the multilayer substrate 103 according to the present example embodiment.

The method of manufacturing the multilayer substrate 103 is almost the same as the method of manufacturing the multilayer substrate 101 shown in the first example embodiment. The method of manufacturing the multilayer substrate 103 is as follows.

First, as shown in FIG. 6A, as each layer before stacking, the resin layer 1C, the resin layer 1E on which the lower ground electrode 23 is formed, the resin layer 1A on which the signal line 24 and the ground electrode 25 are formed, a resin layer 1F, and the resin layer 1D on which the upper ground electrode 23, and the resin layer 1B is formed are provided.

In the present example embodiment, the roughened surface of the ground electrode 23 is located at a surface that is not exposed to the hollow portion CA shown in FIG. 6D. Other configurations are the same as the configurations of the multilayer substrates 101 and 102 according to the first and second example embodiments.

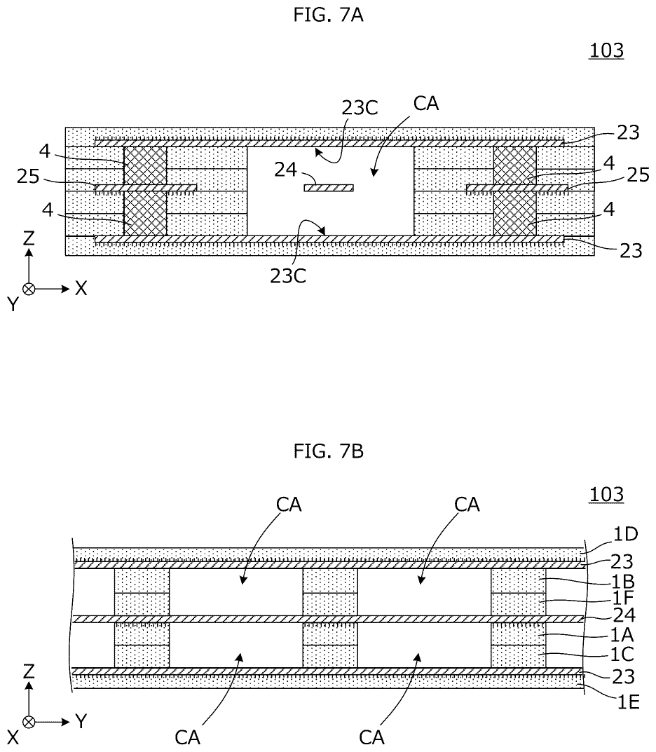

FIGS. 7A and 7B are cross-sectional views of the multilayer substrate 103 according to the present example embodiment. FIG. 7A is a cross-sectional view in the same completed state as the multilayer substrate 103 shown in FIG. 6D. It is a cross-sectional view of an X-Z plane. FIG. 7B is a cross-sectional view of a Y-Z plane.

According to the present example embodiment, the adhesiveness of the ground electrode 23 to the resin layers 1D and 1E is high, so that, as compared with the first and second example embodiments, an adhesive force of a resin layer being a surface layer is high. In addition, the ground electrode 23 originally has a smooth side of the copper foil near the signal line 24, so that the skin resistance is low even when etching is not performed, and its high-frequency characteristics are good. In other words, the etching of the ground electrode 23 does not need to be performed, so that characteristic deterioration due to the etching failure does not easily occur.

It is to be noted that, similarly to the second example embodiment, the thickness in the hollow portion is able to be increased when the ground electrodes 23 and 25 and the signal line 24 are strongly etched, so that improvement in thinness and high-frequency characteristics may also be considered.

### Fourth Example Embodiment

A fourth example embodiment exemplifies a multilayer substrate without a hollow portion below a signal line.

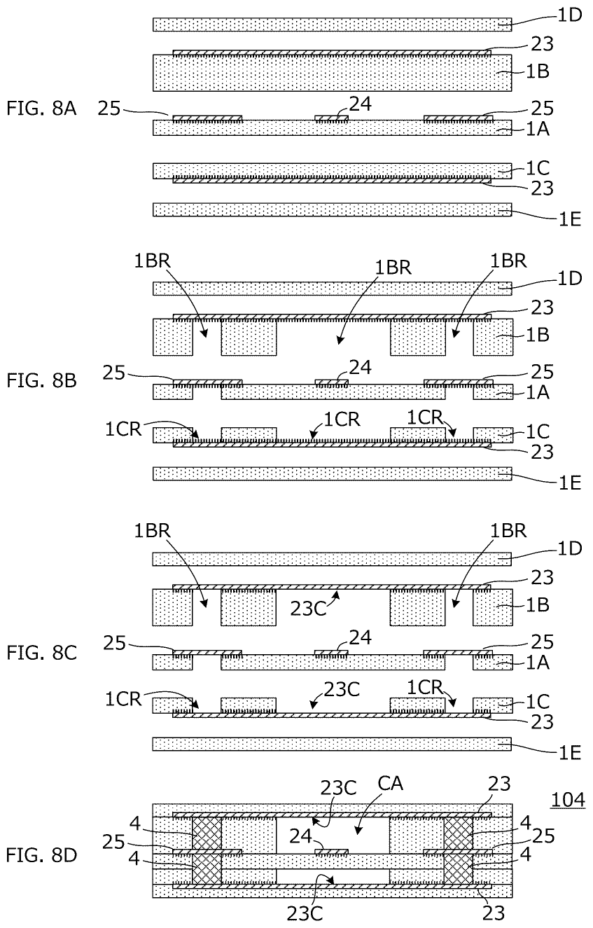

FIGS. 8A to 8D are cross-sectional views of respective stages during manufacturing of the multilayer substrate according to the present example embodiment. FIG. 8D is a cross-sectional view of the multilayer substrate 104 according to the present example embodiment.

The method of manufacturing the multilayer substrate 104 is almost the same as the method of manufacturing the multilayer substrate 101 shown in the first example embodiment. The method of manufacturing the multilayer substrate 104 is as follows.

First, as shown in FIG. 8A, as each layer before stacking, the resin layer 1E, the resin layer 1C on which a lower ground electrode 23 is formed, the resin layer 1A on which the signal line 24 and the ground electrode 25 are formed, and the resin layer 1B on which the upper ground electrode 23 is formed, and the resin layer 1D are provided.

In the present example embodiment, in the stage shown in FIG. 8B, the signal line 24 remains attached to the resin layer 1A. Other configurations are the same as the configurations of the multilayer substrates 101 and 102 according to the first and second example embodiments.

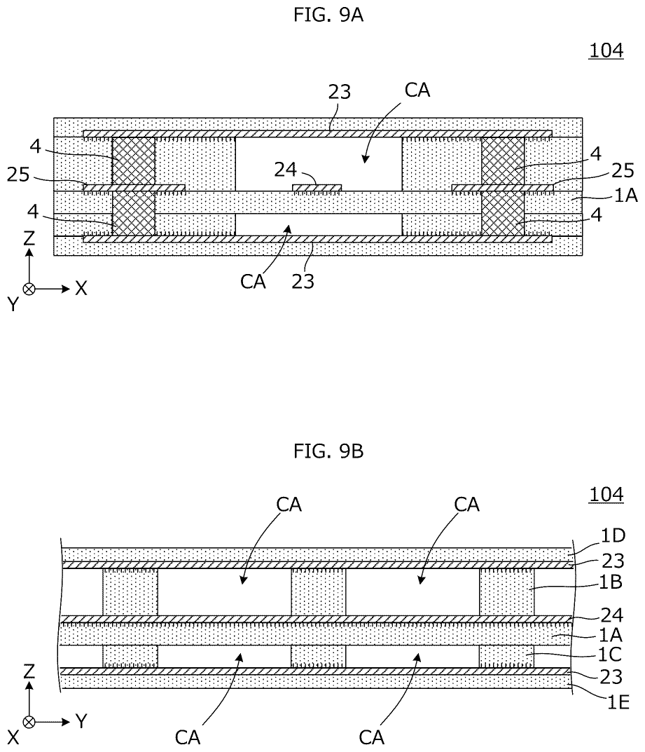

FIGS. 9A and 9B are cross-sectional views of the multilayer substrate 104 according to the present example embodiment. FIG. 9A is a cross-sectional view in the same completed state as the multilayer substrate 104 shown in FIG. 8D. It is a cross-sectional view of an X-Z plane. FIG. 9B is a cross-sectional view of a Y-Z plane.

According to the present example embodiment, although the roughened surface of the signal line 24 remains, the resin layer 1A on which the signal line is formed remains, so that a multilayer substrate with overall high strength is obtained. In addition, a change in the position of the signal line 24 does not easily occur, so that the characteristics of the transmission line provided in the multilayer substrate 104 are stabilized.

### Fifth Example Embodiment

A fifth example embodiment, unlike the fourth example embodiment, exemplifies a multilayer substrate in which the roughened surface of the signal line is near the hollow portion.

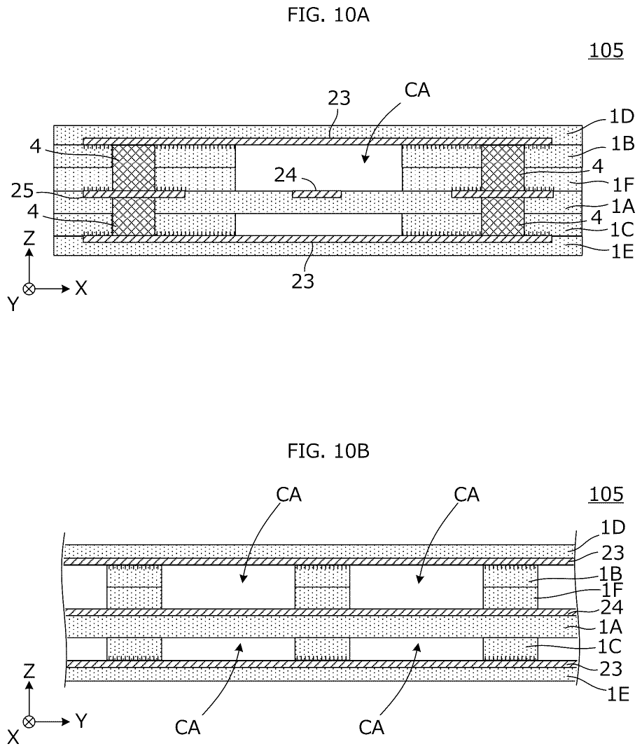

FIGS. 10A and 10B are cross-sectional views of the multilayer substrate 105 according to the present example embodiment. FIG. 10A is a cross-sectional view of an X-Z plane. FIG. 10B is a cross-sectional view of a Y-Z plane.

The multilayer substrate 105 includes a resin layer 1E, a lower ground electrode 23, a resin layer 1C, a signal line 24, a ground electrode 25, a resin layer 1A, a resin layer 1F, an upper ground electrode 23, a resin layer 1B, and a resin layer 1D.

According to the present example embodiment, the roughened surfaces of the surfaces (both surfaces) of the signal line 24 are able to be eliminated.

### Sixth Example Embodiment

A sixth example embodiment exemplifies a multilayer substrate different in a structure of forming a hollow portion from the example embodiments that have been described above.

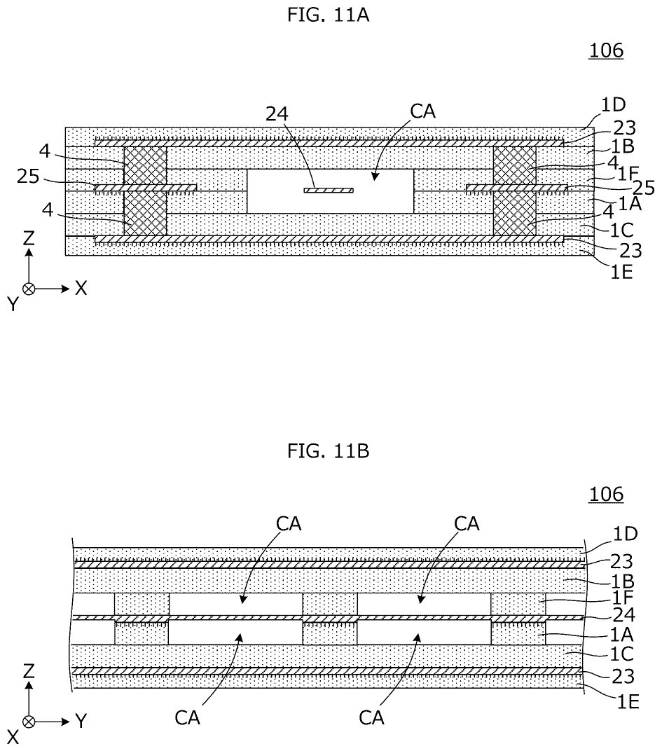

FIGS. 11A and 11B are cross-sectional views of the multilayer substrate 106 according to the present example embodiment. FIG. 11A is a cross-sectional view of an X-Z plane of the multilayer substrate 106 and FIG. 11B is a cross-sectional view of a Y-Z plane.

The multilayer substrate 106 includes a resin layer 1E, a lower ground electrode 23, resin layers 1C and 1A, a signal line 24, a ground electrode 25, a resin layer 1F, a resin layer 1B, an upper ground electrode 23, and a resin layer 1D.

In this manner, a hollow portion CA in which a resin layer is present may be formed on the upper, lower, left, and right sides of the inner surface. According to this structure, the ground electrode 23 is not exposed to the hollow portion and is covered with a resin, and only the signal line 24 is able to reduce the roughening of the electrode of the hollow portion and is also able to reduce the thickness.

### Seventh Example Embodiment

Although the specific examples shown above show the configuration of a transmission line portion of a stripline, a seventh example embodiment exemplifies a multilayer substrate configuring a transmission line of a microstrip line.

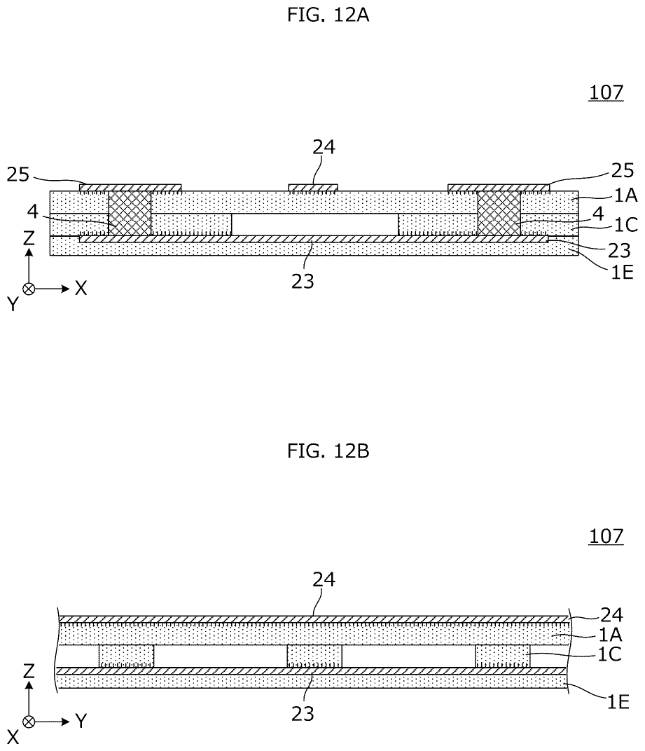

FIGS. 12A and 12B are cross-sectional views of the multilayer substrate 107 according to the present example embodiment. FIG. 12A is a cross-sectional view of an X-Z plane. FIG. 11B is a cross-sectional view of a Y-Z plane.

The multilayer substrate 107 of the present example embodiment is configured by use of the resin layers 1A, 1C, and 1E shown in FIG. 8A in the fourth example embodiment, for example. In short, the multilayer substrate 107 of the present example embodiment is a multilayer substrate configured by stacking the resin layers 1A, 1C, and 1E shown in FIG. 8C.

According to the present example embodiment, a multilayer substrate that includes a microstrip line and is thinner as a whole is obtained.

### Eighth Example Embodiment

An eighth example embodiment exemplifies a multilayer substrate in which necessary layers are adhered through an adhesive layer and a material different from a base material is used on the surface layer of a stacked body.

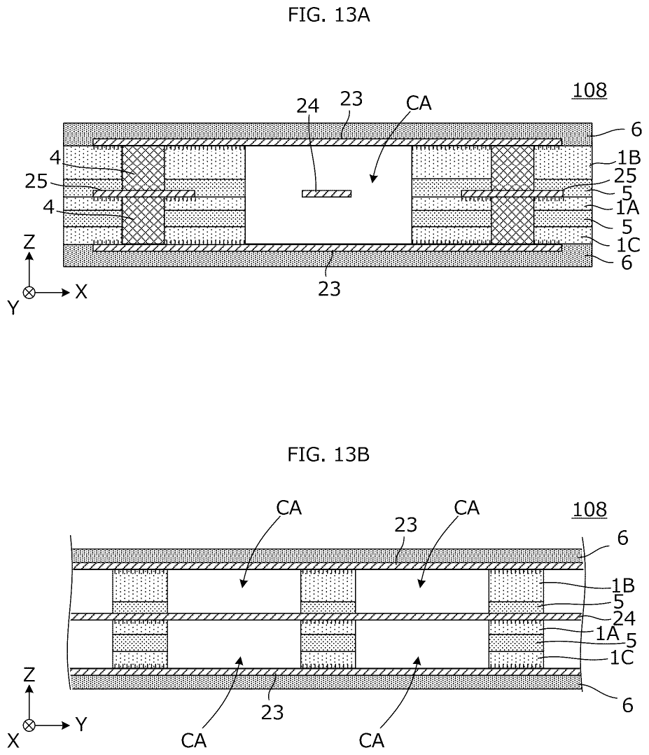

FIGS. 13A and 13B are cross-sectional views of the multilayer substrate 108 according to the present example embodiment. FIG. 13A is a cross-sectional view of an X-Z plane. FIG. 13B is a cross-sectional view of a Y-Z plane.

In the present example embodiment, the resin layer 1A on which the signal line 24 and the ground electrode 25 are formed and the resin layer 1B on which the ground electrode 23 is formed are adhered through the adhesive layer 5. Similarly, the resin layer 1C on which the ground electrode 23 is formed and the resin layer 1A are adhered through the adhesive layer 5. The adhesive layer 5 is a resin layer.

In addition, a resist layer 6 of a different material from the base material is formed on the surface layer of the stacked body in the present example embodiment.

According to the present example embodiment, the resin layers do not need to be directly adhered to each other, so that machining is easier in that regard. In addition, press working in high temperature and high pressure is unnecessary, so that deformation of the hollow portion is able to be reduced. Further, a material different from the base material of the stacked body is able to be used on the surface layer of the stacked body, so that a solder resist layer is easily formed.

### Ninth Example Embodiment

A ninth example embodiment exemplifies a multilayer substrate different in a structure of stacking conductor layer-formed resin layers from the example embodiments that have been described above.

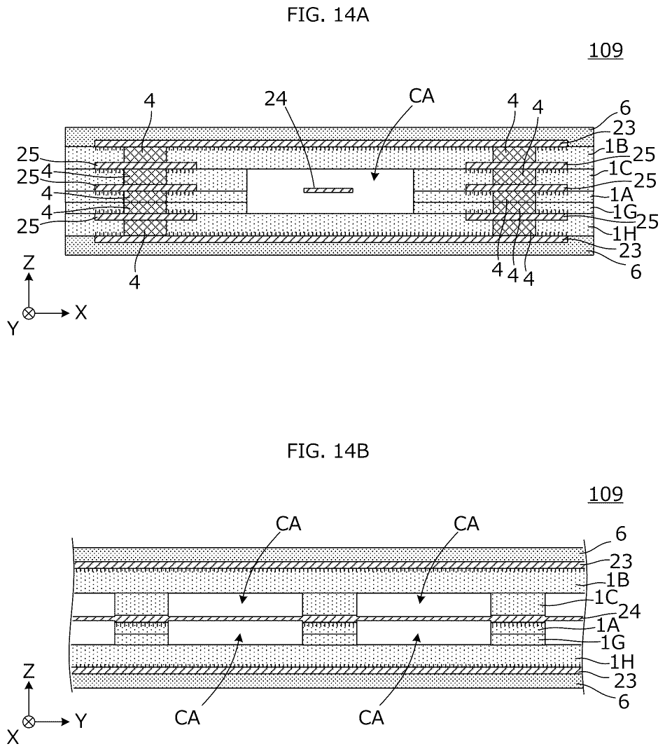

FIGS. 14A and 14B are cross-sectional views of the multilayer substrate 109 according to the present example embodiment. FIG. 14A is a cross-sectional view of an X-Z plane of the multilayer substrate 109 and FIG. 14B is a cross-sectional view of a Y-Z plane.

This multilayer substrate 109 includes resin layers 1A, 1B, 1C, 1G, and 1H, a lower ground electrode 23, an upper ground electrode 23, a signal line 24, a ground electrode 25, an interlayer connection conductor 4, and a resist layer 6.

The signal line 24 and the ground electrode 25 are formed on the upper surface of the resin layer 1A. The upper ground electrode 23 is formed on the upper surface of the resin layer 1B, and the lower ground electrode 23 is formed on the lower surface of the resin layer 1H. The ground electrode 25 is formed on the upper surface of the resin layer 1C, and the ground electrode 25 is formed on the lower surface of the resin layer 1G.

In this manner, a conductor layer is formed on one surface of each of the resin layers 1A, 1B, 1C, 1G, and 1H. The surfaces of the resin layer 1A and resin layer 1G on which no conductor layer is not formed are bonded to each other.

As shown in FIG. 14B, in this example, both surfaces of the signal line 24 exposed in the hollow portion CA are thinly formed by etching, polishing, grinding, or the like. With such a shape, the signal line 24 exposed in the hollow portion CA may be thinned.

In addition, in this example, similarly to the example shown in FIGS. 13A and 13B, the resist layer 6 made of a different material from the base material is formed on the surface layer of the stacked body. According to this structure, the upper ground electrode 23 and the lower ground electrode 23 are protected, and these are able to be electrically insulated.

### Tenth Example Embodiment

A tenth example embodiment exemplifies an electronic device according to the present invention.

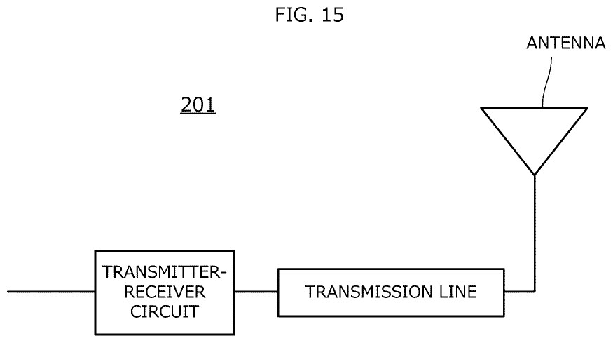

FIG. 15 is a block diagram showing a main configuration of an electronic device according to the present example embodiment. This electronic device 201 includes a transmitter-receiver circuit and an antenna and provides a transmission line between this transmitter-receiver circuit and the antenna. The transmitter-receiver circuit is one example of “a processing portion to process a high-frequency signal.” The transmission line in this electronic device 201 is configured by a multilayer substrate according to an example embodiment of the present invention and is configured by the multilayer substrates shown in each of the first to seventh example embodiments. The high-frequency signal from a 1 GHz band to 1-THz band, for example, propagates through this transmission line.

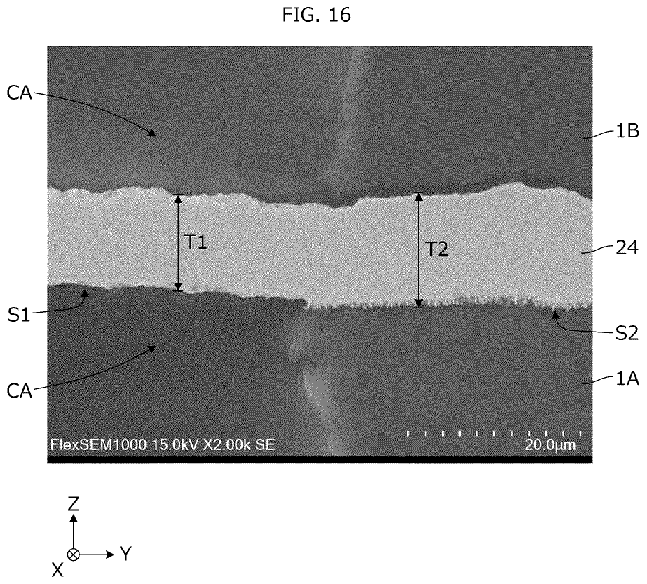

FIG. 16 is a view showing one example of a cross-sectional photograph that has captured the signal line 24.

The surface with a large surface roughness is a surface with a large difference in height in a short wavelength. As shown in FIG. 16, a surface roughness of a surface S1 of the signal line 24 exposed to the hollow portion CA is smaller than a surface roughness of a surface S2 of the signal line 24 embedded in the resin layer 1A. Specifically, the surface S1 of the signal line 24 is etched and is a smooth surface. The surface S2 of the signal line 24 is not etched and remains a rough surface.

In addition, the thickness of a conductor layer is measured from the front end of irregularities of the surface roughness of the conductor layer. As shown in FIG. 16, since the surface S1 of the signal line 24 is etched, so that the peak of the rough surface of the signal line 24 is removed or the rough surface of the signal line 24 is shaved more deeply than the valley of the rough surface of the signal line 24, the signal line 24 in the hollow portion CA is thinner than the signal line 24 other than in the hollow portion CA. For example, the thickness T1 of the signal line 24 in the hollow portion CA is smaller than the thickness T2 of the signal line 24 other than in the hollow portion CA.

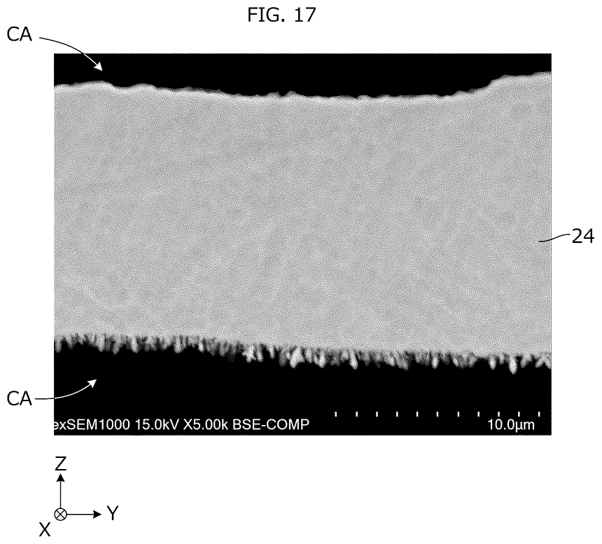

FIG. 17 is a view showing another example of a cross-sectional photograph that has captured the signal line 24. As shown in FIG. 17, the signal line 24 in the hollow portion CA may have a smooth surface on one side and may have a rough surface on the other side.

It is to be noted that a porous body may be placed in a portion of the hollow portion CA.

Finally, the present invention is not limited to the foregoing example embodiments. Various modifications or changes can be appropriately made by those skilled in the art. The scope of the present invention is defined not by the foregoing example embodiments but by the following claims. Furthermore, the scope of the present invention is intended to include all possible modifications or changes from the example embodiments within the scopes of the claims and the scopes of equivalents.

For example, the interlayer connection conductor 4, although being shown as an example to be at the same upper and lower positions as the ground electrode 25 in each example embodiment, may be arranged at a different position (a shifted position).

For example, although each example embodiment shows the single transmission line portion, example embodiments of the present invention are also applicable to a multilayer substrate having a plurality of transmission lines.

Multilayer substrates and electronic devices according to example embodiments of the present invention may be provided as described below.

<1>

A multilayer substrate including a plurality of conductor layer-formed resin layers each including a conductor layer on a principal surface of a resin layer, the conductor layer-formed resin layers include a first conductor layer-formed resin layer in which a first conductor layer is on one principal surface, and a second conductor layer-formed resin layer in which a second conductor layer is on one principal surface, at least a portion of the first conductor layer is a signal line, at least a portion of the second conductor layer is a ground electrode, a hollow portion in which a resin of the resin layer of a region of the first conductor layer-formed resin layer including a portion overlapped by the signal line when viewed in a direction of the stacking is absent and to which the signal line is exposed is provided, and a thickness of the signal line in the hollow portion is smaller than a thickness of the first conductor layer at a portion other than in the hollow portion.

<2>

A multilayer substrate including a plurality of conductor layer-formed resin layers each including a conductor layer on a principal surface of a resin layer, the conductor layer-formed resin layers include a first conductor layer-formed resin layer in which a first conductor layer is on one principal surface, and a second conductor layer-formed resin layer in which a second conductor layer is on one principal surface, at least a portion of the first conductor layer is a signal line, at least a portion of the second conductor layer is a ground electrode, a hollow portion in which a resin of the resin layer of a region of the second conductor layer-formed resin layer including a portion overlapped by the signal line when viewed in a direction of the stacking is absent and to which the ground electrode is exposed is provided, and a thickness of the ground electrode in the hollow portion is smaller than a thickness of the ground electrode other than in the hollow portion.

<3>

The multilayer substrate according to <1> in which a surface roughness of the signal line in the hollow portion is smaller than a surface roughness of the first conductor layer and the second conductor layer at a portion other than in the hollow portion.

<4>

The multilayer substrate according to <2> in which a surface roughness of the ground electrode in the hollow portion is smaller than a surface roughness of the second conductor layer at a portion other than in the hollow portion.

<5>

The multilayer substrate according to <1> or <3> in which an anti-corrosion layer is on a surface of the signal line exposed to the hollow portion of the signal line.

<6>

The multilayer substrate according to <2> or <4> in which an anti-corrosion layer is on a surface of the ground electrode exposed to the hollow portion of the ground electrode.

<7>

The multilayer substrate according to any of <1> to <6> in which an interlayer connection conductor that electrically connects the first conductor layer and the second conductor layer is provided, and a signal propagating through a stripline or a microstrip line including the first conductor layer-formed resin layer, the second conductor layer-formed resin layer, the ground electrode, and the signal line is a high-frequency signal from a 1 GHz band to a 1 THz band.

<8>

An electronic device including the multilayer substrate according to <7>, and a processing portion to process the high-frequency signal propagating through the multilayer substrate.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a plurality of conductor layer-formed resin layers each including a conductor layer on a principal surface of a resin layer; wherein
the conductor layer-formed resin layers include a first conductor layer-formed resin layer in which a first conductor layer is positioned on one principal surface, and a second conductor layer-formed resin layer in which a second conductor layer is positioned on one principal surface;
at least a portion of the first conductor layer is a signal line;
at least a portion of the second conductor layer is a ground electrode; and
the multilayer substrate includes a structure of at least either (A) or (B):
(A) a hollow portion in which a resin of the resin layer of a region of the first conductor layer-formed resin layer including a portion overlapped by the signal line when viewed in a direction of the stacking is absent and to which the signal line is exposed is provided, and a thickness of the signal line in the hollow portion is smaller than a thickness of the first conductor layer at a portion other than in the hollow portion; or
(B) a hollow portion in which a resin of the resin layer of a region of the second conductor layer-formed resin layer including a portion overlapped by the signal line when viewed in a direction of the stacking is absent and to which the ground electrode is exposed is provided, and a thickness of the ground electrode in the hollow portion is smaller than a thickness of the ground electrode other than in the hollow portion.

2. A multilayer substrate comprising:
a plurality of conductor layer-formed resin layers each including a conductor layer on a principal surface of a resin layer; wherein
the conductor layer-formed resin layers include a first conductor layer-formed resin layer in which a first conductor layer is positioned on one principal surface, and a second conductor layer-formed resin layer in which a second conductor layer is positioned on one principal surface;
the first conductor layer includes a first principal surface and the second conductor layer includes a second principal surface;
at least a portion of the first conductor layer is a signal line;
at least a portion of the second conductor layer is a ground electrode; and
the multilayer substrate includes a structure of at least either (C) or (D):
(C) a hollow portion in which a resin of the resin layer of a region of the first conductor layer-formed resin layer including a portion overlapped by the signal line when viewed in a direction of the stacking is absent and to which the first principal surface in the signal line is exposed is provided, and a surface roughness of the first principal surface in the signal line in the hollow portion is smaller than a surface roughness of the first principal surface of the first conductor layer at a portion other than in the hollow portion; or
(D) a hollow portion in which a resin of the resin layer of a region of the second conductor layer-formed resin layer including a portion overlapped by the signal line when viewed in a direction of the stacking is absent and to which the second principal surface in the ground electrode is exposed is provided, and a surface roughness of the second principal surface in the ground electrode in the hollow portion is smaller than a surface roughness of the second principal surface of the second conductor layer at a portion other than in the hollow portion.

3. A multilayer substrate comprising:
a plurality of conductor layer-formed resin layers each including a conductor layer on a principal surface of a resin layer; wherein
the conductor layer-formed resin layers include a first conductor layer-formed resin layer in which a first conductor layer is positioned on one principal surface, and a second conductor layer-formed resin layer in which a second conductor layer is positioned on one principal surface;
at least a portion of the first conductor layer is a signal line;
at least a portion of the second conductor layer is a ground electrode; and
the multilayer substrate includes a structure of at least either (E) or (F):
(E) a hollow portion in which a resin of the resin layer of a region of the first conductor layer-formed resin layer including a portion overlapped by the signal line when viewed in a direction of the stacking is absent and to which the signal line is exposed is provided, and an anti-corrosion layer is provided on a surface of the signal line exposed to the hollow portion of the signal line; or
(F) a hollow portion in which a resin of the resin layer of a region of the second conductor layer-formed resin layer including a portion overlapped by the signal line when viewed in a direction of the stacking is absent and to which the ground electrode is exposed is provided, and an anti-corrosion layer is provided on a surface of the ground electrode exposed to the hollow portion of the ground electrode.

4. The multilayer substrate according to claim 2, comprising the structure of (C); wherein
the signal line includes a first portion in the hollow portion, and a second portion that is spaced away from the first portion in an extension direction of the signal line and is present other than in the hollow portion; and
the surface roughness of the first principal surface in the first portion of the signal line is smaller than the surface roughness of the first principal surface in the second portion of the signal line.

5. The multilayer substrate according to claim 2, comprising the structure of (D); wherein
the ground electrode includes a third portion in the hollow portion, and a fourth portion that is spaced away from the third portion in an extension direction of the signal line and is present other than in the hollow portion; and
the surface roughness of the second principal surface in the third portion of the ground electrode is smaller than the surface roughness of the second principal surface in the fourth portion of the ground electrode.

6. The multilayer substrate according to claim 2, wherein the first conductor layer includes a lateral ground electrode positioned laterally relative to the signal line.

7. The multilayer substrate according to claim 6, comprising the structure of (C), wherein the surface roughness of the first principal surface in the signal line in the hollow portion is smaller than the surface roughness of the first principal surface in the lateral ground electrode.

8. The multilayer substrate according to claim 1, wherein the first conductor layer includes a lateral ground electrode positioned laterally relative to the signal line.

9. The multilayer substrate according to claim 8, comprising the structure of (A), wherein the thickness of the signal line in the hollow portion is smaller than the thickness of the lateral ground electrode.

10. The multilayer substrate according to claim 2, comprising the structures of both (C) and (D); wherein
the first principal surface in the signal line and the second principal surface in the ground electrode are exposed to a same hollow portion;
the signal line includes a first portion in the hollow portion, and a second portion that is spaced away from the first portion in an extension direction of the signal line and is present other than in the hollow portion;
the surface roughness of the first principal surface in the first portion of the signal line is smaller than the surface roughness of the first principal surface in the second portion of the signal line;
the ground electrode includes a third portion in the hollow portion, and a fourth portion that is spaced away from the third portion in an extension direction of the signal line and is present other than in the hollow portion;
the surface roughness of the second principal surface in the third portion of the ground electrode is smaller than the surface roughness of the second principal surface in the fourth portion of the ground electrode; and
the first principal surface in the first portion of the signal line faces the second principal surface in the third portion of the ground electrode.

11. The multilayer substrate according to claim 1, comprising the structures of both (A) and (B).

12. The multilayer substrate according to claim 1, comprising the structure of (A), wherein the signal line includes a portion including:
one principal surface in contact with the hollow portion; and
a different principal surface in contact with the resin layer.

13. The multilayer substrate according to claim 2, comprising the structure of (C), wherein the signal line includes a portion including:
one principal surface in contact with the hollow portion; and
a different principal surface in contact with the resin layer.

14. The multilayer substrate according to claim 1, wherein the first conductor layer includes a portion including:
one principal surface including a first surface roughness and being in contact with a first resin layer; and
a different principal surface including a second surface roughness different from the first surface roughness and being in contact with a second resin layer of which a material is different from a material of the first resin layer.

15. The multilayer substrate according to claim 2, wherein the first conductor layer includes a portion including:
one principal surface including a first surface roughness and being in contact with a first resin layer; and
a different principal surface including a second surface roughness different from the first surface roughness and being in contact with a second resin layer of which a material is different from a material of the first resin layer.

16. The multilayer substrate according to claim 3, wherein the first conductor layer includes a portion including:
one principal surface including a first surface roughness and being in contact with a first resin layer; and
a different principal surface including a second surface roughness different from the first surface roughness and being in contact with a second resin layer of which a material is different from a material of the first resin layer.

17. The multilayer substrate according to claim 1, further comprising an interlayer connection conductor that electrically connects the first conductor layer and the second conductor layer, wherein a signal propagating through a stripline or a microstrip line including the first conductor layer-formed resin layer, the second conductor layer-formed resin layer, the ground electrode, and the signal line is a high-frequency signal from a 1 GHz band to a 1 THz band.

18. The multilayer substrate according to claim 2, further comprising an interlayer connection conductor that electrically connects the first conductor layer and the second conductor layer, wherein a signal propagating through a stripline or a microstrip line including the first conductor layer-formed resin layer, the second conductor layer-formed resin layer, the ground electrode, and the signal line is a high-frequency signal from a 1 GHz band to a 1 THz band.

19. The multilayer substrate according to claim 3, further comprising an interlayer connection conductor that electrically connects the first conductor layer and the second conductor layer, wherein a signal propagating through a stripline or a microstrip line including the first conductor layer-formed resin layer, the second conductor layer-formed resin layer, the ground electrode, and the signal line is a high-frequency signal from a 1 GHz band to a 1 THz band.

20. An electronic device comprising:
the multilayer substrate according to claim 17; and
a processing portion to process the high-frequency signal propagating through the multilayer substrate.
